(19) United States
(12) Patent Application Publication
(10) Pub. No.: US 2025/0370027 A1
(43) Pub. Date: Dec. 4, 2025

(54) APPARATUS AND METHOD FOR STRESS TESTING TRANSISTORS

(71) Applicant: Taiwan Semiconductor Manufacturing Company, Ltd., Hsinchu (TW)

(72) Inventors: Yi-An Lai, Taipei City (TW); Chih-Hua Wang, Hsinchu City (TW); Lei Hoi Kam, Hsinchu City (TW); Cheng Hsun Yang, Taichung City (TW); Tse Ning Yang, Hsinchu County (TW); Chu Fu Chen, Zhubei City (TW); Chan-Hong Chern, Palo Alto, CA (US); Stefan Rusu, Sunnyvale, CA (US)

(21) Appl. No.: 18/893,062

(22) Filed: Sep. 23, 2024

Related U.S. Application Data
(60) Provisional application No. 63/654,341, filed on May 31, 2024.

(51) Int. Cl. G01R 31/26

(52) U.S. Cl. CPC G01R 31/2642

(57) ABSTRACT

A first voltage supply is coupled to a first terminal of a test transistor. A first terminal of a probe circuit is coupled to the first terminal of the test transistor. A second terminal of the probe circuit is coupled to a second terminal of the test transistor. A third terminal of the probe circuit is coupled to a control terminal of the test transistor. A first terminal of the first resistor is coupled to the second terminal of the test transistor. A second terminal of the first resistor is coupled to a second voltage supply. A first input terminal of an amplifier is coupled to a third voltage supply. A second input terminal of an amplifier is coupled to the first terminal of the first resistor. An output terminal of an amplifier is coupled to the control terminal of the test transistor.

### REFERENCE TO RELATED APPLICATION

This application claims the benefit of U.S. Provisional Application No. 63/654,341, filed on May 31, 2024, the contents of which are hereby incorporated by reference in their entirety.

### BACKGROUND

Modern day integrated chips comprise millions or billions of semiconductor devices formed on a semiconductor substrate (e.g., silicon). Semiconductor devices based on silicon, such as transistors and photodiodes, have been a standard in the semiconductor industry for the past four decades. However, semiconductor devices based on alternative materials are receiving increasing attention. For example, semiconductor devices based on group III-N semiconductors, such as gallium nitride (GaN), have found widespread use in high power applications, in optoelectronic applications, in high temperature applications, etc.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a circuit diagram of some embodiments of an apparatus for stress testing a test transistor.

FIG. 2 illustrates diagrams of some embodiments of the performance of the apparatus of FIG. 1.

FIG. 3 illustrates a flow diagram of some embodiments of a method for stress testing the test transistor.

FIG. 4 illustrates a circuit diagram of some other embodiments of the apparatus of FIG. 1.

FIG. 5 illustrates a cross-sectional view of some embodiments of the apparatus of FIG. 4.

FIG. 6 illustrates a flow diagram of some embodiments of a process flow for producing a test transistor.

FIG. 7 illustrates a circuit diagram of some other embodiments of the apparatus of FIG. 4.

FIG. 8 illustrates a circuit diagram of some other embodiments of the apparatus of FIG. 7.

FIG. 9 illustrates a cross-sectional view of some embodiments of the test transistor.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

During integrated chip fabrication, defects can form within or along surfaces of various layers of the chip. For example, when fabricating Gallium Nitride (GaN) high electron mobility transistors (HEMTs), crystal defects (e.g., vacancies, grain boundaries, edge dislocations, screw dislocations, mixed dislocations, etc.) can occur within or along surfaces of the various layers of the transistors. These defects can affect the performance and reliability of the transistors. For example, over time these defects can affect linear drain current degradation, current leakage, ON resistance, threshold voltage, etc. Thus, many integrated chips are subjected to stress testing after fabrication to ensure the reliability and performance of the chips meet certain requirements before the chips are deemed acceptable.

Some stress testing includes applying electrical and thermal stress to a test transistor for a set period of time and determining how the device performance changes as a result of the stress testing. First, an initial performance of the test transistor is measured before stress is applied. Next, the stress test is performed. For example, a high temperature reverse bias (HTRB) stress test includes heating the test transistor to a high temperature (e.g., greater than 100 degrees Celsius) and simultaneously applying a large voltage (e.g., greater than 100 volts) across the test transistor. The test transistor is turned on (e.g., voltage is applied to the control terminal of the test transistor) to cause a current to flow through the test transistor. The high voltage and temperature are maintained for a set period of time to maintain stress on the test transistor. The stress test is concluded by removing the high voltage and high temperature from the transistor. Next, a final performance of the test transistor is measured after the stress testing. Finally, the difference between the initial performance and the final performance of the test transistor is determined.

A challenge with this stress testing is that the ON resistance of the test transistor may increase as the temperature of the test transistor increases and thus the current flowing through the test transistor may decrease during the stress testing. Consequently, the duration of the stress testing may need to be increased. Increasing the duration of the stress testing may increase the cost of the testing and may slow chip production.

In various embodiments of the present disclosure, the voltage at the control terminal of the transistor is adjusted throughout the stress testing so that the current through the transistor remains approximately constant throughout the stress testing (despite changes in the ON resistance during the stress testing). By maintaining constant current through the test transistor throughout the stress testing, the duration of the stress testing can be reduced. As a result, a cost of the testing may be reduced and chip production may be improved.

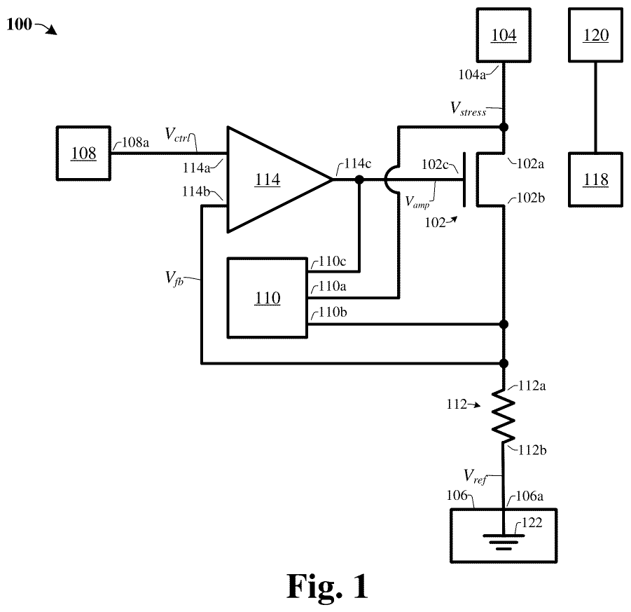

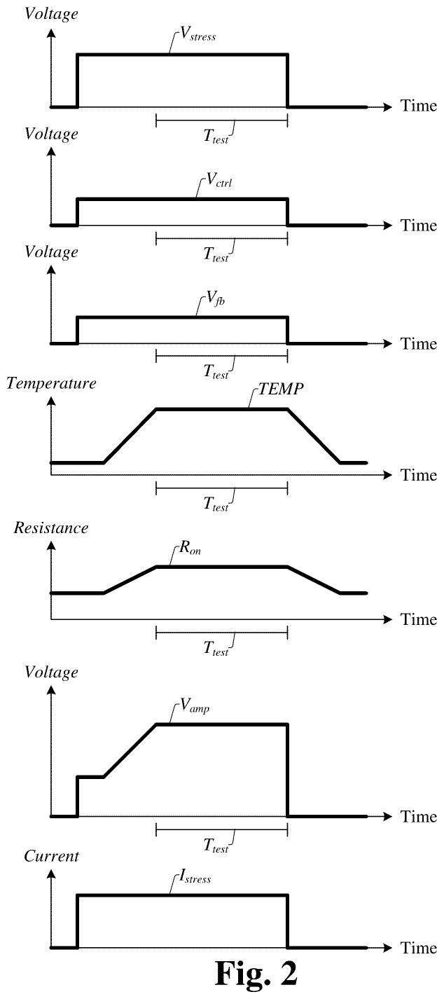

FIG. 1 illustrates a circuit diagram 100 of some embodiments of an apparatus for stress testing a test transistor 102. FIG. 2 illustrates diagrams of some embodiments of the performance of the apparatus of FIG. 1.

Referring to FIG. 1, the apparatus includes a first voltage supply 104, a second voltage supply 106, a third voltage supply 108, a probe circuit 110, a first resistor 112, an amplifier 114, a heater 118, and a heater power supply 120. In some embodiments, the second voltage supply 106 is or is coupled to ground 122.

The test transistor 102 has a first terminal 102a, a second terminal 102b, and a control terminal 102c. The first voltage supply 104 has an output terminal 104a coupled to the first terminal 102a of the test transistor 102. The first resistor 112 has a first terminal 112a coupled to the second terminal 102b of the test transistor 102. The second voltage supply 106 has an output terminal 106a coupled to a second terminal 112b of the first resistor 112. The amplifier 114 has a first input terminal 114a (e.g., a reference terminal), a second input terminal 114b (e.g., a feedback terminal), and an output terminal 114c. The third voltage supply 108 has an output terminal 108a coupled to the first input terminal 114a of the amplifier 114. The second input terminal 114b of the amplifier 114 is coupled to the first terminal 112a of the first resistor 112 (and the second terminal 102b of the test transistor 102). The probe circuit 110 has a first terminal 110a coupled to the first terminal 102a of the test transistor 102, a second terminal 110b coupled to the second terminal 102b of the test transistor 102, and a third terminal 110c coupled to the control terminal 102c of the test transistor 102. In some embodiments, the probe circuit 110 has a fourth terminal (not shown) coupled to a bulk or body terminal (not shown) of the test transistor 102. The heater 118 is near to the test transistor 102. The heater 118 is coupled to the heater power supply 120.

To stress test the test transistor 102 under thermal and electrical stress (e.g., HTRB testing), the heater 118 heats the test transistor 102, the first voltage supply 104 provides a stress voltage Vₛₜᵣₑₛₛ to the first terminal 102a of the test transistor 102, the second voltage supply 106 provides a reference voltage V_{ref} to the second terminal 112b of the first resistor 112, and the third voltage supply 108 provides a control voltage V_{crtl} to the first input terminal 114a of the amplifier 114. The amplifier 114 receives a feedback voltage V_{fb} (e.g., the voltage across the first resistor 112) at the second input terminal 114b. The amplifier 114 increases the magnitude of the amplifier voltage Vₐₘₚ so the test transistor 102 turns ON and passes a stress current Iₛₜᵣₑₛₛ from the first terminal 102a to the second terminal 102b, and the amplifier 114 adjusts the magnitude of the amplifier voltage Vₐₘₚ so that the feedback voltage V_{fb} (at the second input terminal 114b) is approximately equal to the control voltage V_{ctrl} (at the first input terminal 114a), as illustrated in FIG. 2. For example, the amplifier 114 adjusts the magnitude of the amplifier voltage Vₐₘₚ, which increases the current through the test transistor 102 and the first resistor 112, which increases the voltage across the first resistor 112 (the feedback voltage V_{fb}), at least until the voltage across the first resistor 112 (the feedback voltage Vit) is equal to the control voltage V_{ctrl}, as illustrated in FIG. 2.

In some cases, while under thermal and electrical stress, properties of the test transistor 102 change (e.g., the ON resistance Rₒₙ of the test transistor 102 increases) as the temperature TEMP of the test transistor 102 increases, as illustrated in FIG. 2. Yet, because the control voltage V_{ctrl} from the third voltage supply 108 to the first input terminal 114a is constant, and because the amplifier 114 adjusts the amplifier voltage Vₐₘₚ to cause the feedback voltage Vit at the second input terminal 114b to be equal to the control voltage V_{ctrl} at the first input terminal 114a, the feedback voltage Vit at the second input terminal 114b (e.g., the voltage across the first resistor 112) is approximately constant, as illustrated in FIG. 2. Thus, the current through the first resistor 112 is approximately constant and hence the stress current Iₛₜᵣₑₛₛ through the test transistor 102 is approximately constant, even as properties of the test transistor 102 change under stress (e.g., the ON resistance increases), as illustrated in FIG. 2.

Because the current through the test transistor 102 remains approximately constant throughout the stress testing, the duration of the stress testing Tₜₑₛₜ can be reduced (e.g., from about 500 hours to about 10 minutes). For example, by maintaining constant current throughout the stress testing, charge carrier injection into defects within the test transistor 102 (e.g., hot carrier injection) can be induced more quickly and the degradation of the performance (e.g., ON resistance, linear drain current, threshold voltage, leakage, etc.) of the test transistor 102 can be induced more quickly. Thus, the reliability and performance of the device can be tested in a shorter time. By reducing the duration of the stress testing, a cost of the testing can be reduced and chip production can be improved.

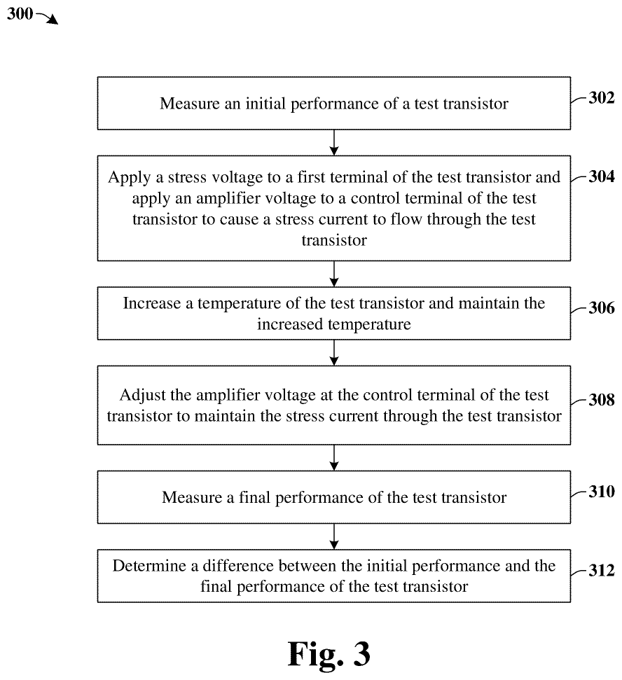

FIG. 3 illustrates a flow diagram 300 of some embodiments of a method for stress testing the test transistor 102. While the method of FIG. 3 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At block 302, measure an initial performance of a test transistor. For example, normal operating voltages are applied to the first terminal 102a and the control terminal 102c of the test transistor 102 while the test transistor 102 is maintained at room temperature, and the performance of the test transistor (e.g., linear drain current, on resistance, gate-to-source leakage, drain-to-source leakage, gate-to-bulk leakage, etc.) is measured by the probe circuit 110. For example, the probe circuit measures a voltage at the first terminal 102a, the second terminal 102b, and the control terminal 102c of the test transistor 102 and measures a current through the test transistor 102 (e.g., from terminal 102a to terminal 102b, from terminal 102c to terminal 102b, from terminal 102c to terminal 102a, from terminal 102c to bulk, etc.).

At block 304, apply a stress voltage to a first terminal of the test transistor and apply an amplifier voltage to a control terminal of the test transistor to cause a stress current to flow through the test transistor. For example, the first voltage supply 104 provides the stress voltage Vₛₜᵣₑₛₛ (e.g., ranging from 300 to 800 volts, from 400 to 700 volts, or some other suitable range), which is substantially higher than the normal operating voltage, to the first terminal 102a of the test transistor 102 for a first period of time Tₜₑₛₜ. Further, the third voltage supply 108 provides a control voltage V_{ctrl} (e.g., ranging from 0.1 to 20 volts, from 1 to 15 volts, from 5 to 10 volts, or some other suitable range) to the first input terminal 114a of the amplifier 114 for the first period of time Tₜₑₛₜ. In turn, the amplifier 114 provides the amplifier voltage Vₐₘₚ to the control terminal 102c of the test transistor 102 for the first period of time Tₜₑₛₜ. As a result, a stress current Iₛₜᵣₑₛₛ flows through the test transistor 102 between the first terminal 102a and the second terminal 102b for the first period of time Tₜₑₛₜ.

At block 306, increase a temperature of the test transistor and maintain the increased temperature. For example, the heater 118 heats the test transistor 102 from a first temperature (e.g., room temperature) to a test temperature (e.g., ranging from 100 to 175 degrees Celsius, from 100 to 150 degrees Celsius, from 125 to 150 degrees Celsius, or some other suitable range) and maintains the test transistor 102 at the test temperature for the first period of time Tₜₑₛₜ.

At block 308, adjust the amplifier voltage at the control terminal of the test transistor to maintain the stress current through the test transistor. For example, in some cases, increasing the temperature TEMP of the test transistor 102 increases the ON resistance Rₒₙ of the test transistor 102. In turn, the amplifier 114 increases the amplifier voltage Vₐₘₚ that it provides to the control terminal 102c of the test transistor 102 in response to the increase in the ON resistance Rₒₙ of the test transistor 102 to maintain the current level of the stress current Iₛₜᵣₑₛₛ through the test transistor 102 despite the increase in the ON resistance Rₒₙ.

At block 310, measure a final performance of the test transistor. For example, after the electrical and thermal stress are removed from the test transistor 102, normal operating voltages are applied to the first terminal 102a and the control terminal 102c of the test transistor 102 while the test transistor 102 is maintained at room temperature and the performance of the test transistor (e.g., linear drain current, on resistance, gate-to-source leakage, drain-to-source leakage, gate-to-bulk leakage, etc.) is measured by the probe circuit 110. For example, the probe circuit measures a voltage at the first terminal 102a, the second terminal 102b, and the control terminal 102c of the test transistor 102 and measures a current through the test transistor 102 (e.g., from terminal 102a to terminal 102b, from terminal 102c to terminal 102b, from terminal 102c to terminal 102a, from terminal 102c to bulk, etc.).

At block 312, determine a difference between the initial performance and the final performance of the test transistor. For example, a difference between the initial linear drain current of the test transistor 102 and the final linear drain current of the test transistor 102 is determined to determine the linear drain current degradation caused by the stress testing. Further, a difference between the initial ON resistance and final ON resistance is determined, a difference between the initial leakage and final leakage is determined, a difference between the initial threshold voltage and final threshold voltage is determined, etc. In some embodiments, the performance of the test transistor 102 is measured and monitored during the stress testing in addition to the initial and final measurements.

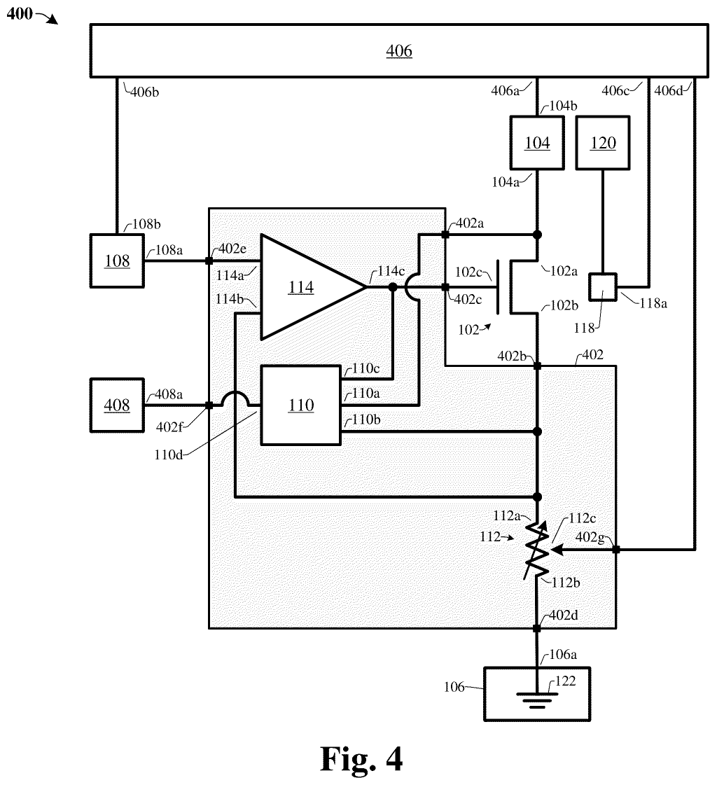

FIG. 4 illustrates a circuit diagram 400 of some embodiments of the apparatus of FIG. 1 in which the probe circuit 110, the first resistor 112, and the amplifier 114 are integrated on an integrated chip 402.

The first terminal 110a of the probe circuit 110 is coupled to a first terminal 402a of the integrated chip 402. The first terminal 402a is coupled to the output terminal 104a of the first voltage supply 104 and the first terminal 102a of the test transistor 102. The second terminal 110b of the probe circuit 110, the first terminal 112a of the first resistor 112, and the second input terminal 114b of the amplifier 114 are coupled to a second terminal 402b of the integrated chip 402. The second terminal 402b is coupled to the second terminal 102b of the test transistor 102. The third terminal 110c of the probe circuit 110 and the output terminal 114c of the amplifier 114 are coupled to a third terminal 402c of the integrated chip 402. The third terminal 402c is coupled to the control terminal 102c of the test transistor 102. The second terminal 112b of the first resistor 112 is coupled to a fourth terminal 402d of the integrated chip 402. The fourth terminal 402d is coupled to the output terminal 106a of the second voltage supply 106 (e.g., ground 122). The first input terminal 114a of the amplifier 114 is coupled to a fifth terminal 402e of the integrated chip. The fifth terminal 402c is coupled to the output terminal 108a of the third voltage supply 108.

In some embodiments, the apparatus further includes a control circuit 406. The control circuit 406 is coupled to the first voltage supply 104 and the third voltage supply 108 and controls the voltage levels output by the first voltage supply 104 and the third voltage supply 108. For example, a first terminal 406a of the control circuit 406 is coupled to a control terminal 104b of the first voltage supply 104. The stress voltage Vₛₜᵣₑₛₛ provided to the first terminal 102a of the test transistor 102 by the first voltage supply 104 can be adjusted by the control circuit 406 to tune the electrical stress across the first terminal 102a and the second terminal 102b of the test transistor 102. For example, in some embodiments, the control circuit 406 controls the first voltage supply 104 to provide 500 volts to the first terminal 102a of the test transistor 102. In some other embodiments, the control circuit 406 controls the first voltage supply 104 to provide 520 volts to the first terminal 102a of the test transistor 102. In some other embodiments, the control circuit 406 controls the first voltage supply to provide 650 volts or some other suitable voltage to the first terminal 102a of the test transistor 102.

Further, a second terminal 406b of the control circuit 406 is coupled to a control terminal 108b of the third voltage supply 108. The control voltage V_{ctrl} provided to the first input terminal 114a of the amplifier 114 by the third voltage supply 108 can be adjusted by the control circuit 406 to tune the stress current Iₛₜᵣₑₛₛ through the test transistor 102 (and thus tune the stress testing duration). For example, in some embodiments, the control circuit 406 controls the third voltage supply 108 to provide 5 volts to the first input terminal 114a of the amplifier 114. In some such embodiments, the resistance of the first resistor is 1000 ohms and thus the stress current through the test transistor 102 is approximately 5 milliamps. In some such embodiments, the stress time (e.g., the amount of time that the stress current is passed through the test transistor 102 while the test transistor 102 is at the test temperature) is 10 minutes.

In some other embodiments, the control circuit 406 controls the third voltage supply 108 to provide 7.5 volts to the first input terminal 114a of the amplifier 114. In some such embodiments, the resistance of the first resistor is 1000 ohms and thus the stress current through the test transistor 102 is approximately 7.5 milliamps. In some such embodiments, the stress time is 7.5 minutes.

In some other embodiments, the control circuit 406 controls the third voltage supply 108 to provide 10 volts or some other suitable voltage to the first input terminal 114a of the amplifier 114. In some such embodiments, the resistance of the first resistor is 1000 ohms and thus the stress current through the test transistor 102 is approximately 10 milliamps. In some such embodiments, the stress time is 5 minutes.

In some embodiments, the control circuit 406 is coupled to the heater 118 (e.g., a third terminal 406c of the control circuit 406 is coupled to a control terminal 118a of the heater 118) and controls the temperature at which the heater 118 maintains the test transistor 102. The temperature of the test transistor 102 can be adjusted by the control circuit 406 to tune the thermal stress applied to the test transistor 102. For example, in some embodiments, the control circuit 406 controls the heater 118 to heat the test transistor 102 to 100 degrees Celsius. In some other embodiments, the control circuit 406 controls the heater 118 to heat the test transistor 102 to 125 degrees Celsius. In some other embodiments, the control circuit 406 controls the heater 118 to heat the test transistor 102 to 150 degrees Celsius or some other suitable temperature.

In some systems, stress testing is accelerated (reduce duration of stress testing) by increasing the thermal stress on the test transistor 102 (e.g., increasing the temperature of the test transistor 102). However, increasing the thermal stress may increase the power consumption of the testing. By using constant current to accelerate the stress testing as described in various embodiment of the disclosure (instead of increasing the temperature during testing to accelerate the stress testing), the temperature of the test transistor can be reduced. Thus, the power consumption of the stress testing can be reduced.

In some embodiments, the apparatus further includes a calculation circuit 408 coupled to the probe circuit 110. For example, the probe circuit 110 has an output terminal 110d coupled to an input terminal 408a of the calculation circuit 408 through a sixth terminal 402f of the integrated chip 402. The calculation circuit 408 receives the measurements taken by the probe circuit (e.g., current measurements, voltage measurements, etc.) and calculates the performance (e.g., ON resistance, leakage, threshold voltage, linear drain current, etc.) of the test transistor 102 based on the measurements from the probe circuit 110. Further, the calculation circuit 408 determines the difference between measurements taken before stress testing and measurements taken after stress testing. Thus, the calculation circuit 408 can determine the performance and reliability degradation of the test transistor 102.

In some embodiments, the first resistor 112 is a variable resistor having a control terminal 112c. The control terminal 112c is coupled to a terminal 406d of the control circuit 406 through a terminal 402g of the integrated chip 402. The resistance of the first resistor 112 can be adjusted to further tune the stress current Iₛₜᵣₑₛₛ through the test transistor (and thus further tune the stress time). For example, in some embodiments, the control circuit 406 controls the first resistor 112 to have a resistance of 500 ohms. In some such embodiments, the voltage at the first input terminal 114a of the amplifier 114 is 5 volts and thus the stress current through the test transistor 102 is approximately 10 milliamps. In some such embodiments, the stress time is 5 minutes.

In some other embodiments, the control circuit 406 controls the first resistor 112 to have a resistance of 1000 ohms. In some such embodiments, the voltage at the first input terminal 114a of the amplifier 114 is 5 volts and thus the stress current through the test transistor 102 is approximately 5 milliamps. In some such embodiments, the stress time is 10 minutes.

In some other embodiments, the control circuit 406 controls the first resistor 112 to have a resistance of 2000 ohms. In some such embodiments, the voltage at the first input terminal 114a of the amplifier 114 is 5 volts and thus the stress current through the test transistor 102 is approximately 2.5 milliamps. In some such embodiments, the stress time is 20 minutes.

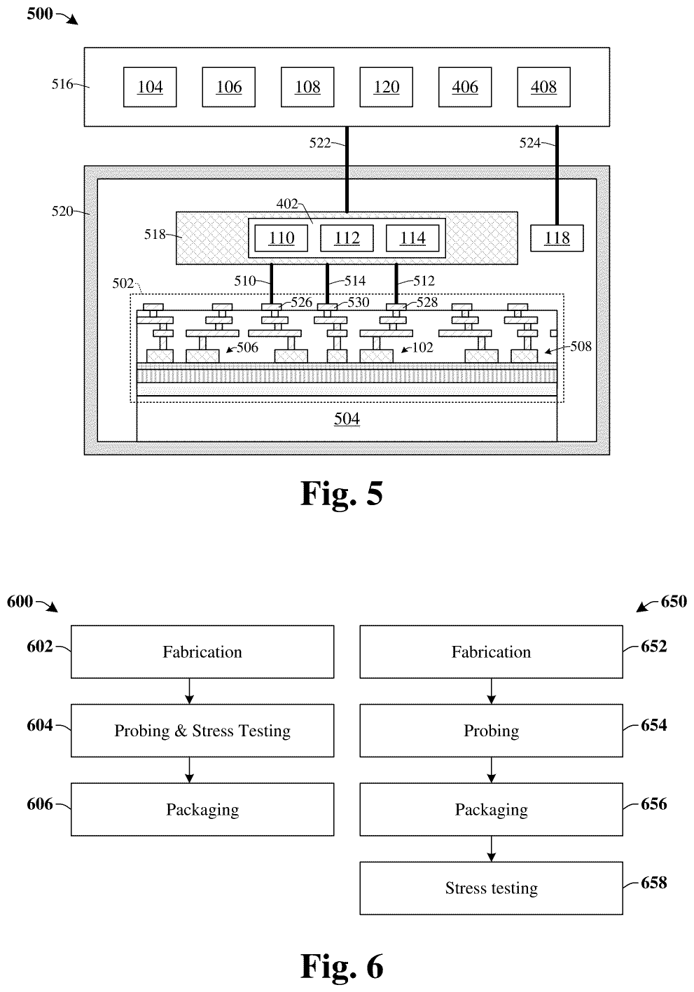

FIG. 5 illustrates a cross-sectional view 500 of some embodiments of the apparatus of FIG. 4.

In some embodiments, the test transistor 102 is on a test wafer 502. Other transistors 506, 508 are on the test wafer 502 and spaced from test transistor 102. In some embodiments, the integrated chip 402 is referred to as a probe card chip and is arranged on a probe card 518. The test wafer 502 is arranged on a wafer holder 504 within a test chamber 520. The heater 118 is in the test chamber 520 and heats the test chamber 520. In some embodiments, the probe card 518 including the integrated chip 402 is in the test chamber 520.

In some embodiments, a first probe 510 extends from the probe card 518 to the test transistor 102 and electrically couples terminal 402a of the integrated chip 402 to the first terminal 102a of the test transistor 102. For example, the first probe 510 extends from a first connection (not shown) on the probe card 518 (which is coupled to terminal 402a of the integrated chip 402) to a first conductive pad 526 on the test wafer 502 (which is coupled to the first terminal 102a of the test transistor 102). A second probe 512 extends from the probe card 518 to the test transistor 102 and electrically couples terminal 402b of the integrated chip 402 to the second terminal 102b of the test transistor 102. For example, the second probe 512 extends from a second connection (not shown) on the probe card 518 (which is coupled to terminal 402b of the integrated chip 402) to a second conductive pad 528 on the test wafer 502 (which is coupled to the second terminal 102b of the test transistor 102). A third probe 514 extends from the probe card 518 to the test transistor 102 and electrically couples terminal 402c of the integrated chip 402 to the control terminal 102c of the test transistor. For example, the third probe 514 extends from a third connection (not shown) on the probe card 518 (which is coupled to terminal 402c of the integrated chip 402) to a third conductive pad 530 on the test wafer 502 (which is coupled to the control terminal 102c of the test transistor 102).

In some embodiments, the first voltage supply 104, the second voltage supply 106, the third voltage supply 108, the heater power supply 120, the control circuit 406, and the calculation circuit 408 are arranged within a test device 516. The test device 516 is coupled to the probe card 518 by external wiring 522. For example, external wiring 522 couples the first terminal 402a of the integrated chip 402 to the first voltage supply 104, the fourth terminal 402d of the integrated chip 402 to the second voltage supply 106 (e.g., ground 122), the fifth terminal 402e of the integrated chip 402 to the third voltage supply 108, and the sixth terminal 402f of the integrated chip 402 to the calculation circuit 408. The test device 516 is coupled to the heater 118 by external wiring 524. For example, external wiring 524 couples the heater power supply 120 to the heater 118 and couples terminal 406c of the control circuit 406 to terminal 118a of the heater 118.

By integrating the first resistor 112 and the amplifier 114 into the probe card 518, the test transistor 102 can be stress tested on the test wafer 502. As a result, parasitic resistance, parasitic inductance, and parasitic capacitance caused by packaging the test transistor 102 can be avoided during the testing. Thus, the testing results may have improved precision and accuracy. Further, stress testing the test transistor 102 on the test wafer 502 may improve a speed of the chip fabrication process and thus the chip production may be improved. Furthermore, a number of sacrificed wafers may be reduced and thus chip production may be further improved.

In some embodiments, the first resistor 112 and the amplifier 114 are integrated into the test wafer 502. For example, the first resistor 112 and the amplifier 114 are formed on the test wafer 502 and are coupled to the test transistor 102 by on-wafer interconnect.

In some embodiments, the test wafer 502 is diced, the test transistor 102 is packaged, the test transistor package is arranged on an evaluation board, and the packaged test transistor 102 is stress tested on the evaluation board. In some embodiments, this package-level testing is performed in addition to the wafer-level testing. In some embodiments, the package-level testing is performed alternatively to the wafer-level testing.

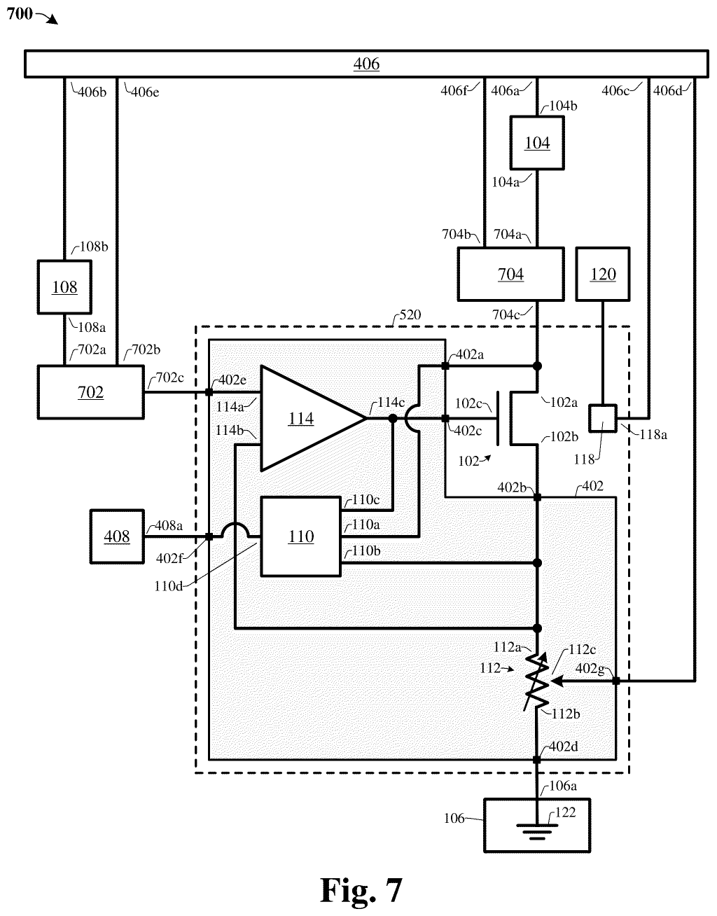

FIG. 6 illustrates a flow diagram 600 of some embodiments of a process flow for producing a test transistor.

At block 602, a wafer is fabricated. For example, a plurality of transistors are formed on a wafer.

At block 604, the wafer is probed to test the transistors on the wafer to ensure they operate properly. Further, the transistors on the wafer are stress tested while on the wafer. In some embodiments, the probing and wafer-level stress testing takes about 1 week. For example, in some embodiments, the probing takes about 1 week and the stress testing takes about 10 minutes.

At block 606, the wafer is diced and the die are packaged. In some embodiments, the dicing and packaging takes about 3 weeks.

FIG. 6 further illustrates a flow diagram 650 of some other embodiments of a process flow of a test transistor.

At block 652, the wafer is fabricated.

At block 654, the wafer is probed to test the transistors on the wafer to ensure they operate properly.

At block 656, the wafer is diced and the die are packaged.

At block 658, the transistors are stress tested. For example, a package including a transistor is stress tested on an evaluation board. In some embodiments, the package-level stress testing takes about 10 minutes.

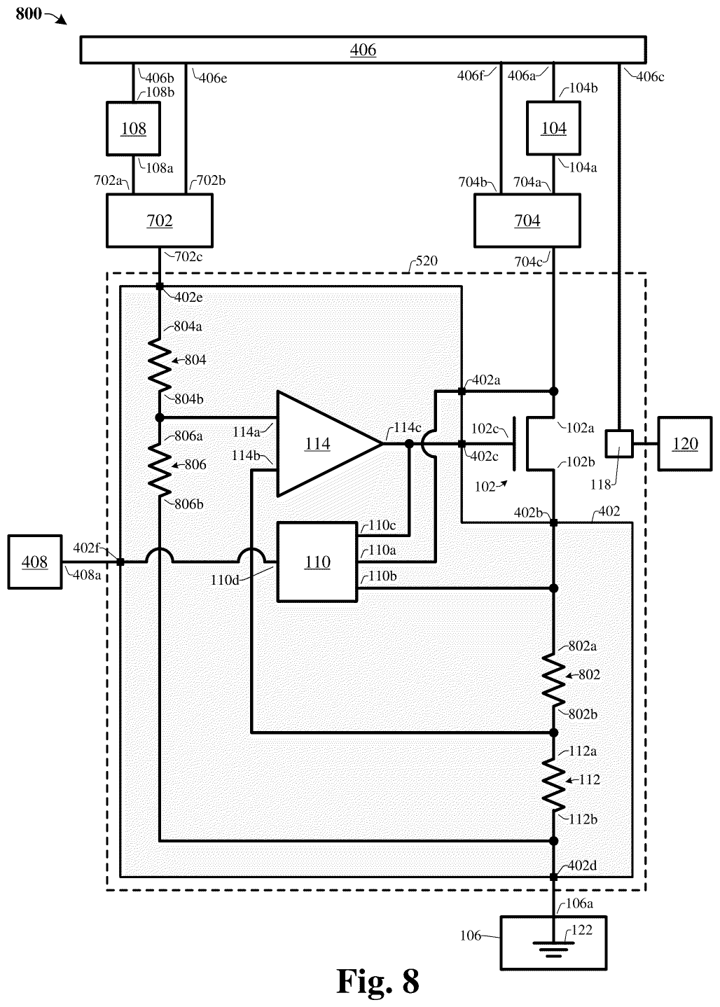

FIG. 7 illustrates a circuit diagram 700 of some embodiments of the apparatus of FIG. 4 in which a first function generator circuit 702 is coupled between the third voltage supply 108 and the amplifier 114.

The first function generator circuit 702 has a first input terminal 702a coupled to the output terminal 108a of the third voltage supply 108, a second input terminal 702b coupled to a terminal 406c of the control circuit 406, and an output terminal 702c coupled to the first input terminal 114a of the amplifier 114 (through terminal 402e of the integrated chip 402).

The first function generator circuit 702 receives the control voltage from the third voltage supply 108 and an input signal from the control circuit 406, and the first function generator circuit 702 outputs a control signal to the first input terminal 114a of the amplifier 114 based on the voltage from the third voltage supply 108 and the input signal from the control circuit 406. In some embodiments, the control signal is a square wave having a maximum voltage set by the third voltage supply 108 and having a frequency and a duty cycle set by the control circuit 406. For example, in some embodiments, the control signal is a square wave signal having a peak voltage ranging from 1 to 15 volts or some other suitable voltage, a frequency ranging from 1000 Hz to 100 million Hz or some other suitable frequency, and a duty cycle ranging from 1% to 50% or some other suitable duty cycle. In some other embodiments, the control signal is a step signal which steps from a first voltage to a second voltage to a third voltage and so on. In other embodiments, the control signal is a ramp signal or some other suitable signal.

In some embodiments, the apparatus further includes a second function generator circuit 704. The second function generator circuit 704 has a first input terminal 704a coupled to the output terminal 104a of the first voltage supply 104, a second input terminal 704b coupled to a terminal 406f of the control circuit 406, and an output terminal 704c coupled to the first terminal 102a of the test transistor 102.

The second function generator circuit 704 receives a voltage from the first voltage supply 104 and an input signal from the control circuit 406, and the second function generator circuit 704 outputs a stress signal to the first terminal 102a of the test transistor 102 based on the voltage from the first voltage supply 104 and the input signal from the control circuit 406. In some embodiments, the stress signal is a square wave having a maximum voltage set by the first voltage supply 104 and having a frequency and a duty cycle set by the control circuit 406. In some other embodiments, the stress signal is a step signal. For example, in some embodiments, the stress signal steps from 0 volts to 400 volts in 25 volt steps. In some other embodiments, the stress signal steps from 0 volts to 600 volts or some other suitable voltage in 50 volt steps or some other suitable step. In some embodiments, the stress signal is a square wave signal having a peak voltage ranging from 400 to 600 volts or some other suitable voltage, a frequency ranging from 1000 Hz to 100 million Hz or some other suitable frequency, and a duty cycle ranging from 1% to 50% or some other suitable duty cycle. In some embodiments, the stress signal is a ramp signal or some other suitable signal.

In some embodiments, in addition or alternative to the HTRB stress test, the test transistor 102 is subjected to a high temperature operation life (HTOL) test in which the temperature of the test transistor 102 is raised to a test temperature ranging from 125 degrees Celsius to 175 degrees Celsius or some other suitable temperature, the frequency of the control signal ranges from 1000 Hz to 100 million Hz or some other suitable frequency, the duty cycle of the control signal ranges from 1 percent to 50 percent duty, the stress voltage stress output at the first voltage supply 104 ranges from 40 volts to 1200 volts, and the leakage of the test transistor 102 is measured. For example, the leakage is measured before the HTOL stress is applied and after the HTOL stress it applied, and the difference between the initial leakage and the final leakage is determined.

In some embodiments, in addition or alternative to the HTRB stress test and/or the HTOL test, the test transistor 102 is subjected to a high temperature current collapse (HTCC) test in which the temperature of the test transistor is raised to a test temperature ranging from 125 degrees Celsius to 175 degrees Celsius or some other suitable temperature, the control signal is a pulse signal having a pulse duration ranging from 1 microsecond to 1 second or some other suitable pulse duration, the control signal is periodic having a period ranging from 1 millisecond to 1 second or some other suitable time period, and the ON resistance of the test transistor 102 is measured before and after the HTCC test.

In some embodiments, in addition or alternative to the stress test, the HTOL test, and/or the HTCC test, the test transistor is subjected to a room temperature current collapse (RTCC) test in which the temperature of the test transistor 102 is set to room temperature (e.g., 25 degree Celsius), the control signal is a pulse signal having a pulse duration ranging from 1 microsecond to 1 second or some other suitable pulse duration, the control signal is periodic having a period ranging from 1 millisecond to 1 second or some other suitable time period, and the ON resistance of the test transistor 102 is measured before and after the RTCC test.

FIG. 8 illustrates a circuit diagram 800 of some embodiments of the apparatus of FIG. 7 in which the apparatus further includes a second resistor 802, a third resistor 804, and a fourth resistor 806.

The second resistor 802 has a first terminal 802a coupled to the second terminal 102b of the test transistor 102 through terminal 402b of the integrated chip 402. The second resistor 802 has a second terminal 802b coupled to the first terminal 112a of the first resistor 112 and the second input terminal 114b of the amplifier 114. The third resistor 804 has a first terminal 804a coupled to the output terminal 702c of the first function generator circuit 702 and/or to the output terminal 108a of the third voltage supply 108 through terminal 402e of the integrated chip 402. The third resistor 804 has a second terminal 804b coupled to the first input terminal 114a of the amplifier 114. The fourth resistor 806 has a first terminal 806a coupled to the second terminal 804b of the third resistor 804 and the first input terminal 114a of the amplifier 114. The fourth resistor 806 has a second terminal 806b coupled to the second voltage supply 106 (e.g., ground 122) through terminal 402d of the integrated chip 402. In some embodiments, the resistors 112, 802, 804, 806 and the amplifier 114 are integrated into the test wafer (e.g., 502 of FIG. 5) and are coupled by on-wafer interconnect.

The first resistor 112 and the second resistor 802 form a first voltage divider which provides a fraction of the voltage at the second terminal 102b of the test transistor 102 to the second input terminal 114b of the amplifier 114. The third resistor 804 and the fourth resistor 806 form a second voltage divider which provides a fraction of the voltage from the third voltage supply 108 to the first input terminal 114a of the amplifier 114.

The second resistor 802 and the third resistor 804 have a first temperature coefficient. The first resistor 112 and the fourth resistor 806 have a second temperature coefficient that is lesser in magnitude than the first temperature coefficient. The second temperature coefficient is substantially low in magnitude so that the resistance of the first resistor 112 and the resistance of the fourth resistor 806 are substantially stable across a range of temperatures. The first temperature coefficient is high in magnitude so that resistance of the second resistor 802 and the resistance of the third resistor 804 change with temperature. For example, when the temperature of the resistors 112, 802, 804, 806 increases during the stress testing from a first temperature to a second temperature, the resistance of the first resistor 112 and the resistor of the fourth resistor 806 remains approximately unchanged while the resistance of the second resistor 802 and the resistance of the third resistor 804 change from a first resistance to a second resistance.

Because the resistance of the second resistor 802 and the resistance of the third resistor 804 change by approximately the same amount, the amplifier voltage Vₐₘₚ output at the output terminal 114c of the amplifier 114 remains approximately unchanged. Thus, the effects of temperature on the output of the amplifier 114 can be reduced so the performance of the apparatus as a whole is less temperature dependent.

In some embodiments, the first resistor 112 and the fourth resistor 806 are silicon chromium (SiCr) thin film resistors (TFRs), and the second resistor 802 and the third resistor 804 are gallium nitride (GaN) two-dimensional electron gas (2DEG) resistors.

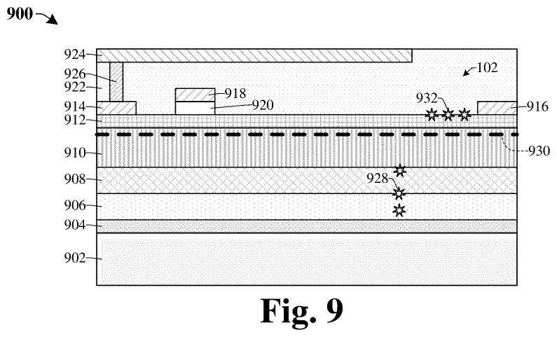

FIG. 9 illustrates a cross-sectional view 900 of some embodiments of the test transistor 102.

In some embodiments, the test transistor 102 is a gallium nitride (GaN) high electron mobility transistor (HEMT). The test transistor 102 is formed along a semiconductor substrate 902. A nucleation layer 904 is over the semiconductor substrate 902. A buffer layer 906 is over the nucleation layer 904. A superlattice layer 908 is over the buffer layer 906. A channel layer 910 is over the superlattice layer 908. A barrier layer 912 is over the channel layer 910. In some embodiments, a two-dimensional electrode gas layer 930 is within the channel layer 910 along the interface between the channel layer 910 and the barrier layer 912.

A first source/drain structure 914 and a second source/drain structure 916 are laterally spaced apart over the barrier layer 912. A gate structure 918 is over the barrier layer 912 and between source/drain structures 914, 916. In some embodiments, a cap layer 920 is between the gate structure 918 and the barrier layer 912. Source/drain structures(s) may refer to a source or a drain, individually or collectively dependent upon the context.

A dielectric structure 922 is over the source/drain structures 914, 916 and the gate structure 918. In some embodiments, a field plate 924 extends from over the first source/drain structure 914 to over the gate structure 918. An interconnect 926 extends from the field plate 924 to the first source/drain structure 914.

In some embodiments, defects 928 (e.g., crystal defects such as vacancies, grain boundaries, edge dislocations, screw dislocations, mixed dislocations, grooves, pits, etc.) are formed along the buffer layer 906 during the fabrication of the test transistor 102. Further, in some embodiments, defects 932 are formed along the surface of the barrier layer 912 during the fabrication of the test transistor 102.

In some embodiments, the semiconductor substrate 902 comprises silicon or some other suitable material. In some embodiments, the nucleation layer 904 comprises aluminum nitride or some other suitable material. In some embodiments, the buffer layer 906 comprises aluminum gallium nitride having a graded aluminum and gallium concentration or some other suitable material. In some embodiments, the superlattice layer 908 comprises gallium nitride or some other suitable material. In some embodiments, the channel layer 910 comprises gallium nitride or some other suitable material. In some embodiments, the barrier layer 912 comprises aluminum gallium nitride or some other suitable material. In some embodiments, the cap layer 920 comprises gallium nitride or some other material. In some embodiments, the source/drain structures 914, 916, the gate structure 918, the field plate 924, and/or the interconnect 926 comprise copper, tungsten, titanium, aluminum, nickel, gold, or some other suitable material. In some embodiments, the dielectric structure 922 comprises silicon dioxide, silicon nitride, or some other suitable material.

Accordingly, in some embodiments, the present disclosure relates to an apparatus including a first voltage supply, a second voltage supply, and a third voltage supply, a probe circuit, a first resistor, and an amplifier. The first voltage supply is coupled to a first terminal of a test transistor. The probe circuit has a first terminal, a second terminal, and a third terminal. The first terminal of the probe circuit is coupled to the first terminal of the test transistor. The second terminal of the probe circuit is coupled to a second terminal of the test transistor. The third terminal of the probe circuit is coupled to a control terminal of the test transistor. The first resistor has a first terminal and a second terminal. The first terminal of the first resistor is coupled to the second terminal of the test transistor. The second terminal of the first resistor is coupled to the second voltage supply. The amplifier has a first input terminal, a second input terminal, and an output terminal. The first input terminal is coupled to the third voltage supply. The second input terminal is coupled to the first terminal of the first resistor. The output terminal is coupled to the control terminal of the test transistor. In some embodiments, the first resistor has a control terminal, and the apparatus further includes a control circuit having a first output terminal coupled to the control terminal of the first resistor. In some embodiments, the first voltage supply has a control terminal coupled to a second output terminal of the control circuit; and the third voltage supply has a control terminal coupled to a third output terminal of the control circuit. In some embodiments, the apparatus includes a first signal generator circuit coupled between the third voltage supply and the first input terminal of the amplifier. In some embodiments, the apparatus includes a second signal generator circuit coupled between the first voltage supply and the first terminal of the test transistor. In some embodiments, the apparatus includes a voltage divider circuit coupled between the third voltage supply and the first input terminal of the amplifier, where the voltage divider circuit has a first terminal coupled to the third voltage supply, a second terminal coupled to the first input terminal of the amplifier, and a third terminal coupled to the second voltage supply. In some embodiments, the apparatus includes a second resistor having a first terminal and a second terminal; the first terminal of the second resistor coupled to the second terminal of the test transistor; and the second terminal of the second resistor coupled to the second input terminal of the amplifier and the first terminal of the first resistor. In some embodiments, the voltage divider circuit comprises a third resistor and a fourth resistor; a first terminal of the third resistor is coupled to the third voltage supply; a second terminal of the third resistor and a first terminal of the fourth resistor are coupled to the first input terminal of the amplifier; and a second terminal of the fourth resistor is coupled to the second voltage supply. In some embodiments, the first resistor and the third resistor have a first temperature coefficient, and the second resistor and the fourth resistor have a second temperature coefficient different than the first temperature coefficient. In some embodiments, the first resistor and the third resistor have a first resistance, and the second resistor and the fourth resistor have a second resistance different than the first resistance. In some embodiments, the first resistor is on an integrated chip and the amplifier is on the integrated chip, the test transistor is on a test wafer separate from the integrated chip, and the apparatus includes: a first wafer probe extending from the integrated chip to the test wafer and coupling the first voltage supply and the first terminal of the probe circuit to the first terminal of the test transistor; a second wafer probe extending from the integrated chip to the test wafer and coupling the first terminal of the first resistor, the second input terminal of the amplifier, and the second terminal of the probe circuit to the second terminal of the test transistor; and a third wafer probe extending from the integrated chip to the test wafer and coupling the output terminal of the amplifier and the third terminal of the probe circuit to the control terminal of the test transistor. In some embodiments, the apparatus includes a test chamber in which the integrated chip and the test wafer are arranged, and a heater in the test chamber. In some embodiments, the first resistor is on an integrated chip, the amplifier is on the integrated chip, and the test transistor is on the integrated chip.

In other embodiments, the present disclosure relates to an apparatus including a first voltage supply, a second voltage supply, a third voltage supply, a probe circuit, a first resistor, and an amplifier. The first voltage supply is coupled to a first terminal of a test transistor and is configured to provide a stress voltage to the first terminal of the test transistor. The probe circuit is coupled to the first terminal of the test transistor, a second terminal of the test transistor, and a control terminal of the test transistor. The probe circuit is configured to measure a voltage across the test transistor and a current through the test transistor. The first resistor is coupled between the second terminal of the test transistor and the second voltage supply. The amplifier is coupled to the test transistor and the first resistor. The amplifier is configured to receive a control voltage from the third voltage supply, provide an amplifier voltage to the control terminal of the test transistor based on a voltage across the first resistor and the control voltage to cause a current having a test current level to flow through the test transistor. The amplifier is configured to adjust the amplifier voltage to maintain the test current level through the test transistor. In some embodiments, the apparatus includes a signal generator configured to generate a control signal according to the control voltage, a frequency, and a duty cycle, and configured to provide the control signal to the amplifier; and the amplifier is configured to provide the amplifier voltage to the control terminal of the test transistor based on the control signal. In some embodiments, the apparatus includes a control circuit configured to adjust a resistance of the first resistor, adjust the control voltage, and adjust the stress voltage. In some embodiments, the apparatus includes a first voltage divider circuit coupled to the third voltage supply and the amplifier and configured to adjust the control voltage based on a temperature of the first voltage divider circuit; and a second voltage divider circuit including the first resistor, the second voltage divider circuit coupled to the test transistor and the amplifier and configured to adjust the voltage across the first resistor based on a temperature of the second voltage divider circuit.

In yet other embodiments, the present disclosure relates to a method including measuring an initial performance of a test transistor before a first period of time. The method includes applying a first voltage to a control terminal of the test transistor to cause a first current to flow through the test transistor for the first period of time after measuring the initial performance of the test transistor. The method includes increasing a temperature of the test transistor from a first temperature to a second temperature and maintaining the temperature of the test transistor at the second temperature for the first period of time. The method includes adjusting the first voltage during the first period of time in response to the increase in the temperature of the test transistor to maintain the first current through the test transistor for the first period of time. The method includes measuring a final performance of the test transistor after the first period of time. The method includes determining a difference between the initial performance of the test transistor and the final performance of the test transistor. In some embodiments, the method includes adjusting a resistance between a second terminal of the test transistor and ground to adjust a magnitude of the first current. In some embodiments, the method includes adjusting the first voltage to adjust a magnitude of the first current. In some embodiments, the method includes oscillating the first voltage according to a frequency and a duty cycle.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An apparatus comprising:
a first voltage supply, a second voltage supply, and a third voltage supply, the first voltage supply coupled to a first terminal of a test transistor;
a probe circuit having a first terminal, a second terminal, and a third terminal, the first terminal of the probe circuit coupled to the first terminal of the test transistor, the second terminal of the probe circuit coupled to a second terminal of the test transistor, and the third terminal of the probe circuit coupled to a control terminal of the test transistor;
a first resistor having a first terminal and a second terminal, the first terminal of the first resistor coupled to the second terminal of the test transistor, the second terminal of the first resistor coupled to the second voltage supply; and
an amplifier having a first input terminal, a second input terminal, and an output terminal, the first input terminal of the amplifier coupled to the third voltage supply, the second input terminal of the amplifier coupled to the first terminal of the first resistor, the output terminal of the amplifier coupled to the control terminal of the test transistor.

2. The apparatus of claim 1, wherein the first resistor has a control terminal, the apparatus further comprising:
a control circuit having a first output terminal coupled to the control terminal of the first resistor.

3. The apparatus of claim 2, wherein the first voltage supply has a control terminal coupled to a second output terminal of the control circuit, and wherein the third voltage supply has a control terminal coupled to a third output terminal of the control circuit.

4. The apparatus of claim 1, further comprising:
a first signal generator circuit coupled between the third voltage supply and the first input terminal of the amplifier.

5. The apparatus of claim 4, further comprising:
a second signal generator circuit coupled between the first voltage supply and the first terminal of the test transistor.

6. The apparatus of claim 1, further comprising:
a voltage divider circuit coupled between the third voltage supply and the first input terminal of the amplifier, the voltage divider circuit having a first terminal coupled to the third voltage supply, a second terminal coupled to the first input terminal of the amplifier, and a third terminal coupled to the second voltage supply.

7. The apparatus of claim 6, further comprising:
a second resistor having a first terminal and a second terminal, the first terminal of the second resistor coupled to the second terminal of the test transistor, the second terminal of the second resistor coupled to the second input terminal of the amplifier and the first terminal of the first resistor,
wherein the voltage divider circuit comprises a third resistor and a fourth resistor, a first terminal of the third resistor coupled to the third voltage supply, a second terminal of the third resistor and a first terminal of the fourth resistor coupled to the first input terminal of the amplifier, a second terminal of the fourth resistor coupled to the second voltage supply.

8. The apparatus of claim 7, wherein the first resistor and the third resistor have a first temperature coefficient, and wherein the second resistor and the fourth resistor have a second temperature coefficient different than the first temperature coefficient.

9. The apparatus of claim 7, wherein the first resistor and the third resistor have a first resistance, and wherein the second resistor and the fourth resistor have a second resistance different than the first resistance.

10. The apparatus of claim 1, wherein the first resistor is on an integrated chip and the amplifier is on the integrated chip, and wherein the test transistor is on a test wafer separate from the integrated chip, the apparatus further comprising:
a first wafer probe extending from the integrated chip to the test wafer and coupling the first voltage supply and the first terminal of the probe circuit to the first terminal of the test transistor;
a second wafer probe extending from the integrated chip to the test wafer and coupling the first terminal of the first resistor, the second input terminal of the amplifier, and the second terminal of the probe circuit to the second terminal of the test transistor; and
a third wafer probe extending from the integrated chip to the test wafer and coupling the output terminal of the amplifier and the third terminal of the probe circuit to the control terminal of the test transistor.

11. The apparatus of claim 10, the apparatus further comprising:
a test chamber in which the integrated chip and the test wafer are arranged; and
a heater in the test chamber.

12. The apparatus of claim 1, wherein the first resistor is on an integrated chip, the amplifier is on the integrated chip, and the test transistor is on the integrated chip.

13. An apparatus comprising:
a first voltage supply, a second voltage supply, and a third voltage supply, the first voltage supply coupled to a first terminal of a test transistor and configured to provide a stress voltage to the first terminal of the test transistor;
a probe circuit coupled to the first terminal of the test transistor, a second terminal of the test transistor, and a control terminal of the test transistor, the probe circuit configured to measure a voltage across the test transistor and a current through the test transistor;
a first resistor coupled between the second terminal of the test transistor and the second voltage supply; and
an amplifier coupled to the test transistor and the first resistor, the amplifier configured to receive a control voltage from the third voltage supply, provide an amplifier voltage to the control terminal of the test transistor based on a voltage across the first resistor and the control voltage to cause a current having a test current level to flow through the test transistor, the amplifier configured to adjust the amplifier voltage to maintain the test current level through the test transistor.

14. The apparatus of claim 13, further comprising:
a signal generator configured to generate a control signal according to the control voltage, a frequency, and a duty cycle, and configured to provide the control signal to the amplifier,
wherein the amplifier is configured to provide the amplifier voltage to the control terminal of the test transistor based on the control signal.

15. The apparatus of claim 13, further comprising:
a control circuit configured to adjust a resistance of the first resistor, adjust the control voltage, and adjust the stress voltage.

16. The apparatus of claim 13, further comprising:
a first voltage divider circuit coupled to the third voltage supply and the amplifier and configured to adjust the control voltage based on a temperature of the first voltage divider circuit; and
a second voltage divider circuit including the first resistor, the second voltage divider circuit coupled to the test transistor and the amplifier and configured to adjust the voltage across the first resistor based on a temperature of the second voltage divider circuit.

17. A method comprising:
measuring an initial performance of a test transistor before a first period of time;
applying a first voltage to a control terminal of the test transistor to cause a first current to flow through the test transistor for the first period of time after measuring the initial performance of the test transistor;
increasing a temperature of the test transistor from a first temperature to a second temperature and maintaining the temperature of the test transistor at the second temperature for the first period of time;
adjusting the first voltage during the first period of time in response to the increase in the temperature of the test transistor to maintain the first current through the test transistor for the first period of time;
measuring a final performance of the test transistor after the first period of time; and
determining a difference between the initial performance of the test transistor and the final performance of the test transistor.

18. The method of claim 17, further comprising:
adjusting a resistance between a second terminal of the test transistor and ground to adjust a magnitude of the first current.

19. The method of claim 17, further comprising:
adjusting the first voltage to adjust a magnitude of the first current.

20. The method of claim 17, further comprising:
oscillating the first voltage according to a frequency and a duty cycle.
